(19) United States
(12) Patent Application Publication
(10) Pub. No.: US 2012/0097681 A1
(43) Pub. Date: Apr. 26, 2012

(54) WATERPROOFING METHOD AND STRUCTURE

(75) Inventors: HO-YUAN LIN, TUCHENG CITY (TW); CHING-FENG HSIEH, TAIPEI CITY (TW)

(73) Assignee: ASKEY COMPUTER CORP., TAIPEI (TW)

(21) Appl. No.: 12/957,515

(22) Filed: Dec. 1, 2010

(30) Foreign Application Priority Data
Oct. 26, 2010 (TW) 099136551

(51) Int. Cl. B65D 53/00; H05K 13/00

(52) U.S. Cl. 220/378; 29/592.1

(57) ABSTRACT

A waterproofing method and structure are applicable to an electronic device having a first casing and a second casing, the first casing having a first adjoining-brim peripherally disposed thereon, and the second casing having a peripheral second adjoining-brim for adjoining the first adjoining-brim. The method includes forming a convex portion circumferentially along the first adjoining-brim; forming a concave portion circumferentially along the second adjoining-brim, the concave portion corresponding in position to the convex portion; disposing a resilient unit in the concave portion, the resilient unit including a body and a soft interfering element protruding therefrom; coupling the first and second adjoining-brims together such that the convex portion presses against the soft interfering element to enable deformation thereof, thereby forming a first interfering structure. The waterproof effect achieved by coupling the first and second adjoining-brims together is not compromised by the stress resulting from the deformation of the soft interfering element.

### CROSS-REFERENCE TO RELATED APPLICATION

This non-provisional application claims priority under 35 U.S.C. §119(a) on Patent Application No(s). 099136551 filed in Taiwan, R.O.C. on Oct. 26, 2010, the entire contents of which are hereby incorporated by reference.

### FIELD OF THE TECHNOLOGY

The present invention relates waterproofing methods and structures, and more particularly, to a waterproofing method and structure which are applicable to an electronic device having a first casing and a second casing and are effective in providing a waterproofing function.

### BACKGROUND

Referring to FIG. 1a, there is shown a schematic cross-sectional view of a waterproofing structure before assembly thereof according to the prior art. According to the prior art, as regards a waterproofing structure for use with an electronic device, a lower casing 2 of the electronic device has a concave portion 22 with an O-ring 4 circumferentially disposed therein, and an upper casing 6 of the electronic device has a convex portion 62 corresponding in position to the concave portion 22. The convex portion 62 becomes received in the concave portion 22 as soon as the upper casing 6 and the lower casing 2 are coupled together. A force F generated as a result of the coupling of the upper casing 6 and the lower casing 2 is exerted upon the O-ring 4 through the convex portion 62 of the upper casing 6, thus causing deformation of the O-ring 4. The deformation of the O-ring 4 prevents external moisture (or dust) from intruding into the inside of the electronic device via a casing seam 8 resulting from the coupling of the upper casing 6 and the lower casing 2, as shown in a schematic cross-sectional view of FIG. 1b.

However, the O-ring 4 is of a round cross section before being subjected to any force, and thus once the convex portion 62 presses against the O-ring 4, the direction of the deformation of the O-ring 4 will be unpredictable, or, in other words, a counteracting force F′ generated as a result of the aforesaid deformation of the O-ring 4 is never uniform. For example, in the aforesaid situation, the O-ring 4 may deform outward when subjected to a force, and thus the outer portion of the O-ring 4 is subjected to the force to a greater extent than the inner portion of the O-ring 4 in terms of the uneven distribution and strength of the force. If the casings 2, 6 of the electronic device is made of a plastic or a material of low rigidity, the aforesaid uneven distribution of the force is likely to cause deformation of the upper and lower casing seam, thereby preventing the casing seam from being seamless and hermetically sealed. The outcome of the aforesaid unfavorable situation is a great reduction in the waterproofing function of the waterproofing structure.

In view of the drawbacks of the prior art, Taiwan Patent M381599, entitled Portable Electronic Device Combination Structure Having Improved Waterproofing Structure, proposes replacing the O-ring with an airtight soft structure for achieving the desirable waterproofing function. Nonetheless, the airtight soft structure is made of rubber or a plastic, and a hollow core structure has to be centrally formed inside the airtight soft structure made of rubber or a plastic so as to achieve the required waterproofing structure. However, a drawback of M381599 is that the hollow core structure incurs manufacturing costs. Therefore, it is imperative to provide a waterproofing method and structure which is effective in waterproofing and overcoming the drawbacks of a conventional waterproofing structure.

### SUMMARY

It is a primary objective of the present invention to provide a waterproofing method for preventing a casing seam of an electronic device from deforming which might otherwise compromise the waterproofing function of the casing seam.

Another objective of the present invention is to provide a waterproofing structure for use with an electronic device to enhance the waterproof protection for the electronic device.

In order to achieve the above and other objectives, the present invention provides a waterproofing method applicable to an electronic device having a first casing and a second casing. The first casing has a first adjoining-brim. The second casing has a second adjoining-brim. The first and second adjoining-brims are coupled together. The waterproofing method comprises the steps of: forming a convex portion circumferentially along the first adjoining-brim on the first casing, such that the convex portion is circumferentially disposed at the rim of the first casing; forming a concave portion circumferentially along the second adjoining-brim on the second casing, such that the concave portion corresponds in position to the convex portion, wherein the convex portion becomes received in the concave portion as soon as the upper casing and the lower casing are coupled together; disposing a resilient unit at the concave portion, the resilient unit comprising a body and a soft interfering element protruding therefrom; and coupling the first adjoining-brim and the second adjoining-brim together so as for the convex portion to press and deform the soft interfering element and thus convert the deformed soft interfering element into a first interfering structure.

In order to achieve the above and other objectives, the present invention provides a waterproofing structure applicable to an electronic device having a first casing and a second casing. The first casing has a first adjoining-brim. The second casing has a second adjoining-brim. The first and second adjoining-brims are coupled together. The waterproofing structure comprises a convex portion, a concave portion, and a resilient unit. The convex portion is circumferentially formed along the first adjoining-brim and disposed on the first casing. The concave portion is circumferentially formed along the second adjoining-brim and disposed on the second casing. The concave portion corresponds in position to the convex portion. The resilient unit is received in the concave portion. The resilient unit comprises a body and a soft interfering element. The soft interfering element extends from and protrudes out of the body. Upon the coupling of the first adjoining-brim and the second adjoining-brim, the convex portion becomes received in the concave portion to press against and deform the soft interfering element such that the deformed soft interfering element is converted into a first interfering structure.

Compared with the prior art, the waterproofing method and structure of the present invention involves using a resilient unit having a body and a soft interfering element protruding from the body, converting the soft interfering element into a first interfering structure for providing a waterproofing function without altering the original design of the casings of an electronic device, and preventing the resilient unit deforming unduly or unevenly upon the coupling of the casings, so as to ensure that the casings can be hermetically sealed in a seamless manner. Also, the present invention further enhances the waterproofing effect, as the casings are provided with a hard interfering element that serves two purposes, namely fixing the resilient unit in position, and forming a second interfering structure.

Accordingly, the waterproofing method and structure of the present invention not only overcomes the drawbacks of the prior art, that is, the conventional resilient unit deforms unduly or unevenly and thus prevents the casings from being hermetically sealed in a seamless manner, but also gives a higher level of ingress protection (IP) to electronic devices.

### BRIEF DESCRIPTION OF THE DRAWINGS

A detailed description of further features and advantages of the present invention is given below so that a person skilled in the art can understand and implement the technical contents of the present invention and readily comprehend the objectives, features, and advantages thereof by reviewing the disclosure of the present specification and the appended claims in conjunction with the accompanying drawings, in which:

FIG. 1a is a schematic cross-sectional view of a waterproofing structure before assembly thereof according to the prior art;

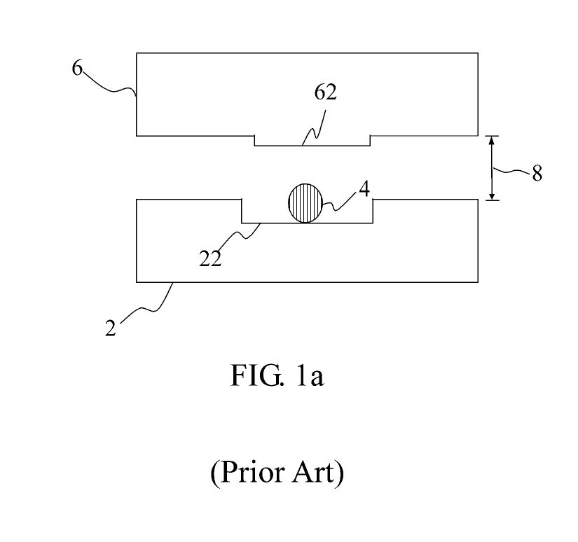

FIG. 1b is a schematic cross-sectional view of a waterproofing structure after assembly thereof according to the prior art;

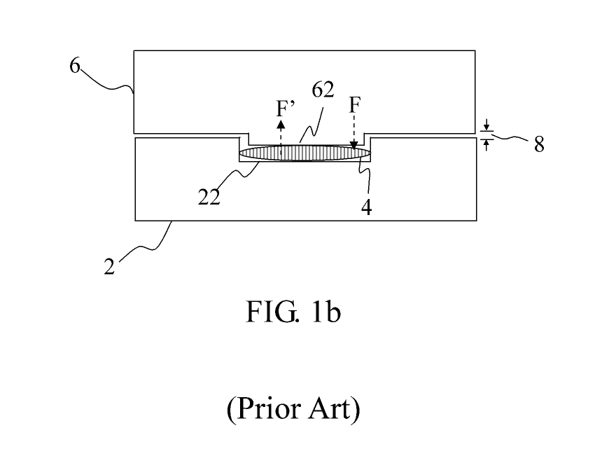

FIG. 2 is a flow chart of a waterproofing method according to a first embodiment of the present invention;

FIG. 3 is a flow chart of the waterproofing method according to a second embodiment of the present invention;

FIG. 4a is a schematic cross-sectional view of the waterproofing structure before assembly thereof according to a third embodiment of the present invention;

FIG. 4b is a schematic cross-sectional view of the waterproofing structure after assembly thereof according to the third embodiment of the present invention;

FIG. 5a is a schematic cross-sectional view of the waterproofing structure before assembly thereof according to a fourth embodiment of the present invention; and

FIG. 5b is a schematic cross-sectional view of the waterproofing structure after assembly thereof according to the fourth embodiment of the present invention.

### DETAILED DESCRIPTION

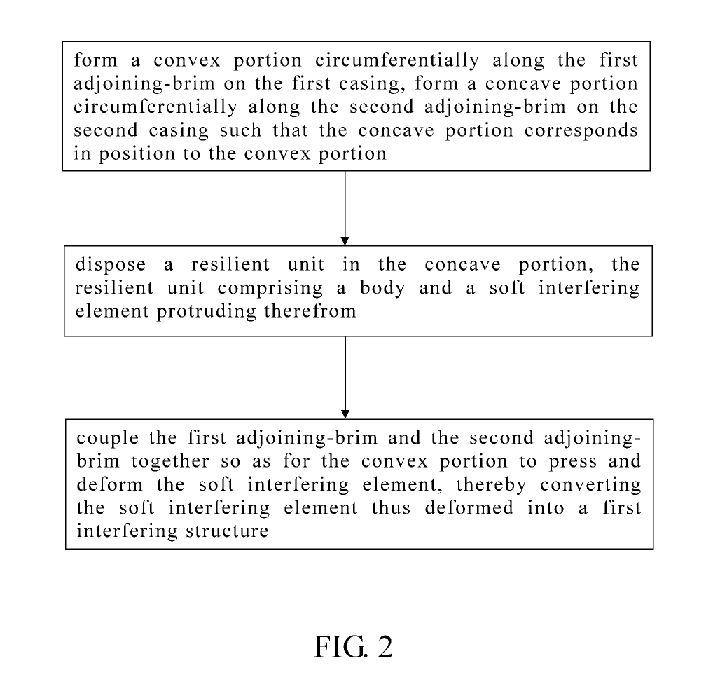

Referring to FIG. 2, there is shown a flow chart of a waterproofing method according to a first embodiment of the present invention. As shown in FIG. 2, the waterproofing method is applicable to an electronic device having a first casing and a second casing. The first casing has a first adjoining-brim. The second casing has a second adjoining-brim. The first and second adjoining-brims are coupled together. The waterproofing method comprises the steps of: forming a convex portion circumferentially along the first adjoining-brim on the first casing, such that the convex portion is circumferentially disposed at the rim of the first casing; forming a concave portion circumferentially along the second adjoining-brim on the second casing, such that the concave portion corresponds in position to the convex portion; disposing a resilient unit in the concave portion, the resilient unit comprising a body and a soft interfering element protruding therefrom, wherein the body is of a quadrilateral or rectangular cross section, and the soft interfering element is a pyramid, wherein the pyramid is defined as a solid cone having a polygonal base and the sides of the polygonal base extend to a common vertex; coupling the first adjoining-brim and the second adjoining-brim together so as for the convex portion to press against the soft interfering element and thereby cause the deformation thereof, thereby converting the soft interfering element into a first interfering structure.

Hence, once the convex portion presses against the soft interfering element of the resilient unit, the soft interfering element at the concave portion deforms. Given its relatively small size, the soft interfering element does not, despite its deformation, generate sufficient deformation-induced counteracting force for deforming the first adjoining-brim of the first casing.

Once the convex portion of the first casing exerts a downward force upon the soft interfering element and the body, the soft interfering element will deform instantly under the downward force. Then, the deformed soft interfering element conveys the downward force to the body, thereby causing the body to deform as well. A point to note is that the soft interfering element is effective in spreading the downward force. Upon its deformation, the deformed body does not have any effect on the coupling of the first adjoining-brim and the second adjoining-brim.

The convex portion not only presses against the soft interfering element but also presses against the body of the resilient unit and thereby deforms the body. However, with the body being of a quadrilateral or rectangular cross section, the convex portion is capable of pressing against the body evenly and thereby bringing about the uniform deformation of the body, not to mention that a counteracting force thus generated is evenly applied to the casing seam to thereby avoid deformation thereof which might otherwise compromise ingress protection (IP).

In this embodiment, a plurality of said soft interfering elements can protrude from the surface of the body. Upon the coupling of the first adjoining-brim and the second adjoining-brim, the convex portion presses against the soft interfering elements to thereby convert the soft interfering elements into a plurality of first interfering elements. The number of the soft interfering elements is subject to changes as needed.

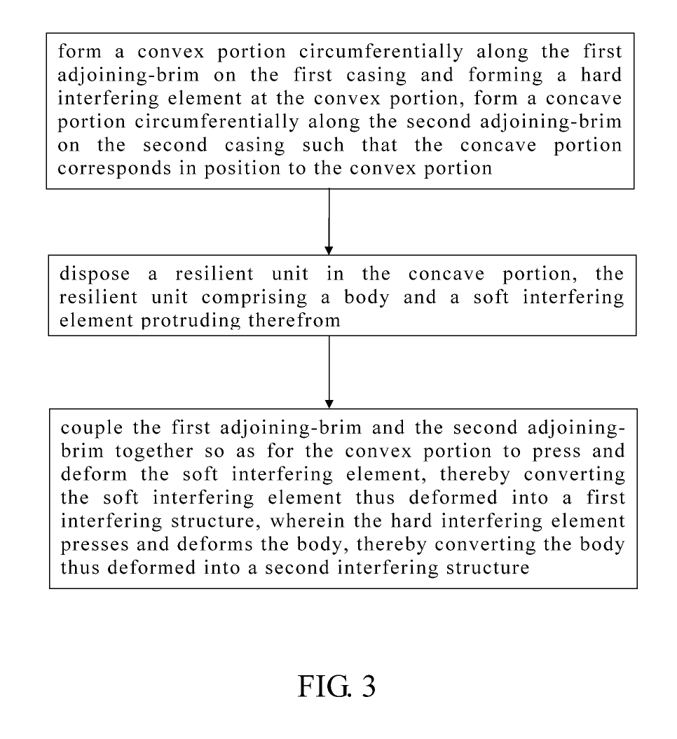

Referring to FIG. 3, there is shown a flow chart of the waterproofing method according to a second embodiment of the present invention. As shown in FIG. 3, in addition to the steps disclosed in the first embodiment of the waterproofing method, the waterproofing method further comprises, in the second embodiment, the step of: forming a hard interfering element at the convex portion, and enabling, upon the coupling of the first adjoining-brim and the second adjoining-brim, the hard interfering element to press and position the body of the resilient unit so as to deform the body and form a second interfering structure therefrom.

In this embodiment, the soft interfering element and the hard interfering element are asymmetrically disposed at the convex portion and the concave portion, respectively. Hence, the hard interfering element which protrudes from the convex portion is located at one end of the convex portion, and the hard interfering element does not necessarily correspond in position to the soft interfering element. Upon the coupling of the first adjoining-brim of the first casing and the second adjoining-brim of the second casing, the hard interfering element presses against the body of the resilient unit and thereby deforms the body, and a second interfering structure is formed from a portion of the body, after the hard interfering element has pressed against the portion of the body. The second interfering structure further enhances the waterproofing function. In addition, the hard interfering structure is effective in pressing against the body and thereby positioning the body. A point to note is that the hard interfering element can be of any shape as needed, provided that the hard interfering element protrudes from the convex portion.

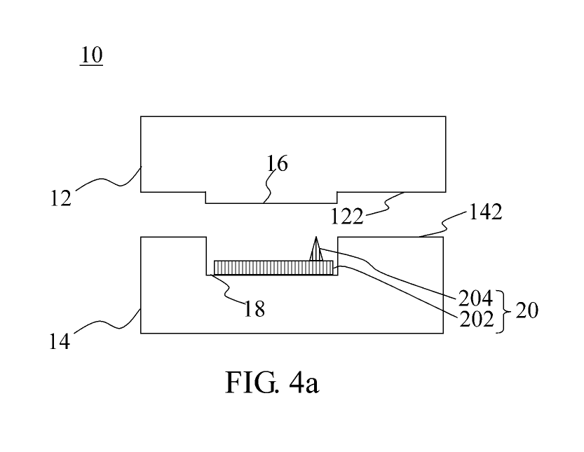

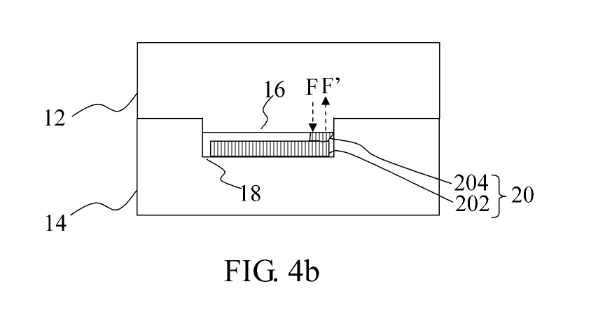

Referring to FIGS. 4a and 4b, there are shown schematic cross-sectional views of the waterproofing structure 10 before and after assembly thereof according to a third embodiment of the present invention, respectively. As shown in FIG. 4a, the waterproofing structure 10 is applicable to an electronic device having a first casing 12 and a second casing 14. FIG. 4a is a cross-sectional view that shows the coupling-related portions of the first casing 12 and the second casing 14, but does not show the first casing 12 and the second casing 14 in its entirety. The first casing 12 has a first adjoining-brim 122. The second casing 14 has a second adjoining-brim 142. The first and second adjoining-brims 122, 142 are configured to be coupled together. The waterproofing structure 10 comprises a convex portion 16, a concave portion 18, and a resilient unit 20. The convex portion 16 is circumferentially formed along the first adjoining-brim 122 and disposed on the first casing 12. The concave portion 18 is circumferentially formed along the second adjoining-brim 142 and disposed on the second casing 14. The concave portion 18 corresponds in position to the convex portion 16. The resilient unit 20 is received in the concave portion 18. The resilient unit 20 comprises a body 202 and a soft interfering element 204. The soft interfering element 204 extends from and protrudes out of the body 202. The body 202 of the resilient unit 20 is of a quadrilateral or rectangular cross section. The soft interfering element 204 is a solid cone. In this embodiment, the body 202 is of a rectangular cross section for illustrative purpose only. In another embodiment, the body 202 and the soft interfering element 204 are made of rubber. In addition, after the first adjoining-brim 122 has been coupled to the second adjoining-brim 142, the convex portion 16 becomes received in the concave portion 18 to press and deform the soft interfering element 204, such that the soft interfering element 204 thus deformed is converted into a first interfering structure.

Referring to FIG. 4b, upon the coupling of the first casing 12 and the second casing 14, the convex portion 16 circumferentially formed along the first adjoining-brim 122 of the first casing 12 is inserted into the concave portion 18 circumferentially formed along the second adjoining-brim 142 of the second casing 14 to thereby press against the soft interfering element 204 of the resilient unit 20. A point to note is that once the convex portion 16 of the first casing 12 exerts a downward force upon the soft interfering element 204 of the resilient unit 20, the soft interfering element 204 will deform instantly under the downward force F, and in consequence the body 202 in the concave portion 18 is further pressed and deformed. The first interfering structure is formed as a result of the contact and compression between the soft interfering element 204 and the body 202, and between the convex portion 16 and the concave portion 18, so as to provide a waterproofing function. Also, since the soft interfering element 204 deforms when subjected to the force F, the deformed soft interfering element 204 exerts a counteracting force F′ upon the convex portion 16. However, the soft interfering element 204 deforms the least when subjected to the force F, and thus the counteracting force F′ is never strong enough to deform the casings. The present invention provides a waterproofing structure having the first interfering structure for enhancing the waterproofing function of the waterproofing structure without compromising the hermetic sealing between the first adjoining-brim 122 of the first casing 12 and the second adjoining-brim 142 of the second casing 14.

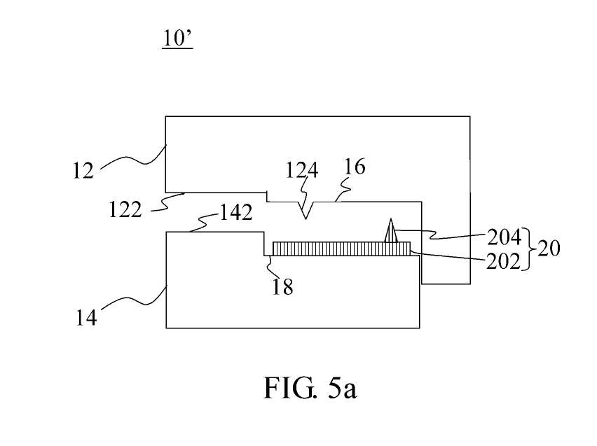

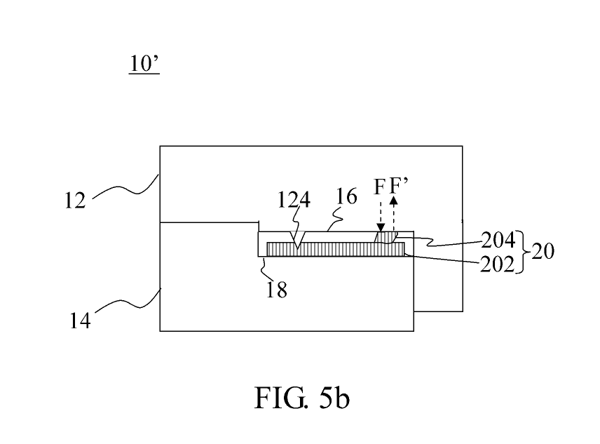

Referring to FIGS. 5a and 5b, there are shown schematic cross-sectional views of a waterproofing structure 10′ before and after assembly thereof according to a fourth embodiment of the present invention, respectively. As shown in FIG. 5a, the waterproofing structure 10′ is applicable to an electronic device having the first casing 12 and the second casing 14. The first casing 12 has the first adjoining-brim 122. The second casing 14 has the second adjoining-brim 142. The first and second adjoining-brim 122, 142 are coupled together. The waterproofing structure 10′ of the fourth embodiment has the same convex portion 16, concave portion 18, and resilient unit 20 as the waterproofing structure 10 of the third embodiment does. The first casing 12 further comprises a hard interfering element 124. The hard interfering element 124 extends from and protrudes out of the convex portion 16. The hard interfering element 124 and the soft interfering element 204 are asymmetrically disposed at the convex portion 16 and the body 202, respectively, as soon as the first adjoining-brim 122 and the second adjoining-brim 142 are coupled together. A point to note is that the hard interfering element 124 is not restricted to any specific shape; instead, the hard interfering element 124 of the present invention will fall within the scope thereof, provided that the hard interfering element 124 protrudes from the convex portion 16.

Referring to FIG. 5b, upon the coupling of the first casing 12 and the second casing 14, the convex portion 16 circumferentially formed along the first adjoining-brim 122 of the first casing 12 is inserted into the concave portion 18 circumferentially formed along the second adjoining-brim 142 of the second casing 14 to thereby press against the soft interfering element 204 of the resilient unit 20. The soft interfering element 204 of the resilient unit 20 deforms under a force F exerted upon the convex portion 16; meanwhile, the hard interfering element 124 at the convex portion 16 presses against the body 202 of the resilient unit 20. Hence, both the body 202 and the soft interfering element 204 bear the downward force F exerted by the hard interfering element 124 and the convex portion 16, and thus the body 202 in the concave portion 18 deforms. The contact and compression between the hard interfering element 124 and the body 202 bring about the formation of the second interfering structure for providing a waterproofing function. A point to note is that, in this embodiment, the hard interfering element 124 is of a relatively small size which accounts for the relatively mild deformation of the body 202, even though the hard interfering element 124 presses against the body 202. Hence, the body 202 is unlikely to exert the counteracting force F′ upon the hard interfering element 124 excessively and cause the deformation of the casings. Last but not least, with the hard interfering element 124 pressing against the body 202 in part, the body 202 can be positioned.

In conclusion, with a first interfering structure and a second interfering structure, a waterproofing structure of the present invention not only precludes waterproofing effect deterioration which might otherwise occur whenever a casing seam deforms under a counteracting force unduly exerted upon casings, but also is effective in enhancing and augmenting the waterproofing effect.

Compared with the prior art, the waterproofing method and structure of the present invention involves using a resilient unit having a soft interfering element, converting the soft interfering element into a first interfering structure for providing a waterproofing function without altering the original design of the casings of an electronic device, and preventing the casings from deforming and thus failing to be hermetically sealed due to an undue counteracting force generated by the resilient unit upon the coupling of the casings, so as to ensure that the casings can be hermetically sealed in a seamless manner Also, the present invention further enhances the waterproofing effect, as the casings are provided with a hard interfering element that serves two purposes, namely fixing the resilient unit in position, and forming a second interfering structure.

Accordingly, the waterproofing method and structure of the present invention not only overcomes the drawbacks of the prior art, that is, the conventional resilient unit deforms unduly or unevenly and thus prevents the casings from being hermetically sealed in a seamless manner, but also gives a higher level of ingress protection (IP) to electronic devices.

The foregoing embodiments are provided to illustrate and disclose the technical features of the present invention so as to enable persons skilled in the art to understand the disclosure of the present invention and implement the present invention accordingly, and are not intended to be restrictive of the scope of the present invention. Hence, all equivalent modifications and replacements made to the foregoing embodiments should fall within the scope of the present invention as set forth in the appended claims. Accordingly, the scope of protection for the present invention should be defined by the appended claims.

What is claimed is:

1. A waterproofing method applicable to an electronic device having a first casing and a second casing, the first casing having a first adjoining-brim, the second casing having a second adjoining-brim, the first and second adjoining-brims being coupled together, the waterproofing method comprising the steps of:
forming a convex portion circumferentially along the first adjoining-brim on the first casing; forming a concave portion circumferentially along the second adjoining-brim on the second casing, the concave portion corresponding in position to the convex portion, wherein the convex portion becomes received in the concave portion as soon as the first adjoining-brim is coupled to the second adjoining-brim;
disposing a resilient unit in the concave portion, the resilient unit comprising a body and a soft interfering element protruding from the body; and
coupling the first adjoining-brim and the second adjoining-brim together so as for the convex portion to press and deform the soft interfering element, thereby converting the soft interfering element thus deformed into a first interfering structure.

2. The waterproofing method of claim 1, further comprising the step of:
forming a hard interfering element at the convex portion, and enabling, upon the coupling of the first adjoining-brim and the second adjoining-brim, the hard interfering element to press and position the body of the resilient unit so as to deform the body and form a second interfering structure therefrom.

3. A waterproofing structure applicable to an electronic device having a first casing and a second casing, the first casing having a first adjoining-brim, the second casing having a second adjoining-brim for being coupled with the first adjoining-brim, the waterproofing structure comprising:
a convex portion circumferentially formed along the first adjoining-brim on the first casing;
a concave portion circumferentially formed along the second adjoining-brim on the second casing, the concave portion corresponding in position to the convex portion; and
a resilient unit received in the concave portion, the resilient unit comprising a body and a soft interfering element protruding from the body, wherein, upon the coupling of the first adjoining-brim and the second adjoining-brim, the convex portion becomes received in the concave portion to press and deform the soft interfering element, thereby converting the soft interfering element thus deformed into a first interfering structure.

4. The waterproofing structure of claim 3, wherein the body is of a quadrilateral or rectangular cross section.

5. The waterproofing structure of claim 3, wherein the soft interfering element of the resilient unit is a solid cone.

6. The waterproofing structure of claim 3, further comprising a hard interfering element protruding from the convex portion, wherein, upon the coupling of the first adjoining-brim and the second adjoining-brim, the hard interfering element presses and positions the body of the resilient unit, thereby converting the body thus deformed into a second interfering structure.

7. The waterproofing structure of claim 3, wherein the body and the soft interfering element are made of rubber.
